(19) United States
(12) Patent Application Publication
(10) Pub. No.: US 2024/0413195 A1
(43) Pub. Date: Dec. 12, 2024

(54) SEMICONDUCTOR DEVICES WITH A CURRENT GAIN LAYOUT

(71) Applicant: Micron Technology, Inc., Boise, ID (US)

(72) Inventor: Takashi Ishihara, Tokyo (JP)

(21) Appl. No.: 18/668,134

(22) Filed: May 18, 2024

Related U.S. Application Data
(60) Provisional application No. 63/472,151, filed on Jun. 9, 2023.

(51) Int. Cl. H01L 29/06; H01L 21/762; H01L 23/522; H01L 29/417; H10B 10/00; H10B 12/00

(52) U.S. Cl. CPC H01L 29/0607; H01L 21/76224; H01L 23/5226; H01L 29/41758; H10B 10/12; H10B 12/05

(57) ABSTRACT

A semiconductor device including a substrate; a first active region disposed in the substrate, the first active region having one or more first type channels and a first plurality of doped regions; a second active region disposed in the substrate, the second active region having one or more second type channels and a second plurality of doped regions, the second active region being physically separated from the first active region by a STI region; an intermediate wiring layer disposed above the substrate, the intermediate wiring layer having a plurality of fingers connected to the first plurality of doped regions and the second plurality of doped regions, respectively; and a metal wiring layer having a source finger and a drain finger, wherein the source finger is connected to a first group of the plurality of fingers, and the drain finger is connected to a second group of the plurality of fingers.

### CROSS-REFERENCE TO RELATED APPLICATION(S)

The present application claims priority to U.S. Provisional Patent Application No. 63/472,151, filed Jun. 9, 2023, the disclosure of which is incorporated herein by reference in its entirety.

### TECHNICAL FIELD

The disclosed embodiments relate to semiconductor devices, and in particular, to semiconductor transistor devices having a current-gain layout.

### BACKGROUND

Semiconductor devices (e.g., transistor devices) can include semiconductor circuits configured to switch electronic signals. The transistor devices can include at least three terminals (e.g., gate, source, and drain) that connect to external circuits. To operate the transistor devices, voltage is controlled across a pair of the terminals, which controls the current through another pair of terminals. Accordingly, the transistor devices can operate in a first state that enables current flow across the terminals and a second state that restricts the current flow. For example, in transistor devices, electric current from the source terminal to the drain terminal can be restricted when a voltage, that is lower than a threshold voltage, is applied between the gate and source terminals. The transistor devices can be configured to provide a targeted amount of current (e.g., drain-source current (I_{DS}) through the corresponding terminals (e.g., drain and source). For example, a layout, a total number of channels, a size of the channel, etc. of the transistor devices can be controlled to provide the targeted amount of current.

### BRIEF DESCRIPTION OF THE DRAWINGS

FIG. 1 depicts an example circuit diagram of an input buffer in accordance with an embodiment of the present technology.

FIG. 2 depicts a first layout of a first transistor device in accordance with an embodiment of the present technology.

FIG. 3 depicts a cross-sectional view of a second transistor device in accordance with an embodiment of the present technology.

FIG. 4 depicts a cross-sectional view of a third transistor device in accordance with an embodiment of the present technology.

FIG. 5 depicts a plan view of a second layout of the first transistor device in accordance with an embodiment of the present technology.

FIG. 6 depicts a plan view of a third layout of the first transistor device in accordance with an embodiment of the present technology.

FIG. 7 is a flow diagram illustrating an example method of manufacturing the first transistor device in accordance with an embodiment of the present technology.

FIG. 8 is another flow diagram illustrating another example method of manufacturing the first transistor device in accordance with an embodiment of the present technology.

FIG. 9 is a schematic view of a system that includes a memory device in accordance with an embodiment of the present technology.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

Transistor devices are essential components of semiconductor devices such as dynamic random access memory (DRAM) memory which stores digital data in capacitors. In DRAM devices, the capacitors are connected to corresponding transistors which are configured to amplify or refresh the charge stored in each capacitor. The transistor devices can also be connected to a control circuit of the memory device that periodically read the charge stored in memory capacitors and refreshes the capacitor by writing the charge back. Specifically, transistor devices can be used in data queue input buffers to amplify and control flow of electrical signals input to or output from capacitors of memory device.

As a base unit of a circuit, transistors can be used to design a semiconductor memory device. For planar metal-oxide-semiconductor field effect (MOSFET) transistors, each transistor may have diffusion regions disposed in an active region of a substrate and a gate attached to the substrate and disposed between the diffusion regions, e.g., a source region and a drain region. The gate can be a terminal or an electrical connection that supplies the control voltage (e.g., a specific voltage relative to the source) that regulates the operating state of the corresponding transistor. According to the gate voltage, the drain-source current can flow between the drain region and the source region. The transistor may have a size or a dimension that influences the amount of drain-source current. A width of the transistor that is orthogonal to a current flow direction that goes across the gate and between the source region and the drain region represents a size of the current corridor or a number of electrons or holes that can simultaneously travel across the source region and the drain region. In addition, the width of the corresponding active region may be equal to width of the transistor and can be a transistor parameter that influences its drain-source current capacity.

As described in greater detail below, the present technology disclosed herein relates to semiconductor devices, systems with semiconductor devices, and related methods for providing a current-gain layout in the semiconductor devices. In the embodiments described below, the semiconductor devices (e.g., transistors) can include sectional transistor devices that have at least two separate sections (e.g., active regions) that are tied by interconnection wiring layers connected to gate, source, and drain regions of each one of the separate sections. Within each section, the sectional transistor device can include two or more channels or transistor units connected in parallel.

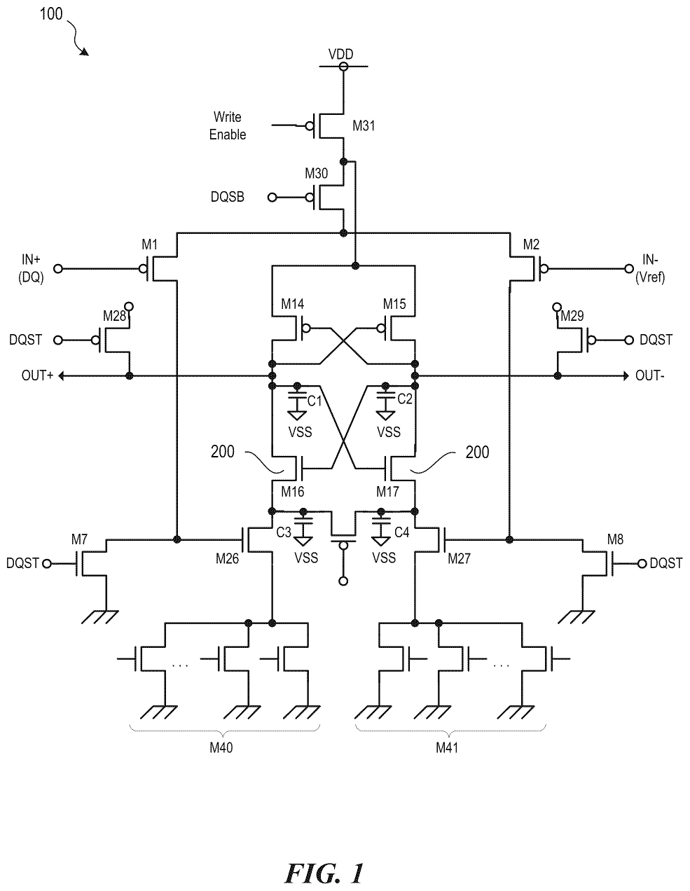

The transistor device configuration presented in this disclosure can be implemented in semiconductor devices to achieve high performances. For example, in a data queue input buffer circuit, a differential amplifier is often used in conjunction with other circuit components such as resistors and capacitors to provide data signals filtering and amplification. The differential amplifier may comprise a group of transistor devices, each of which may contribute or impact the performance of data queue input buffer circuit. FIG. 1 illustrates an example circuit diagram of a data queue input buffer 100 in accordance with an embodiment of the present technology. In some embodiments, the input buffer 100 including sectional transistor devices 200 at one or more portions therein can be implemented for a memory device (e.g., a DRAM device). For example, the input buffer 100 can be included in one or more data terminal (DQ) connections (e.g., within input buffers) that are configured to receive a data (DQ) signal to be written into a memory location.

The input buffer 100 can include one or more transistors (e.g., N-channel transistors and/or P-channel transistors) configured to receive and process corresponding input signals such as a write enable signal, a DQ system signal (e.g., DQSB, DQST, etc.), the data (DQ) signal, or a combination thereof. In some embodiments, the DQ system signal can include the DQSB signal corresponding to a bar signal of a data strobe signal (DQS), the DQST corresponding to a true signal of DQS, or a combination thereof. Accordingly, the input buffer 100 can generate an output signal based on receiving and processing the input signals.

In some embodiments, the input buffer 100 can include a P-channel transistor (M31) controlled by the write enable signal (e.g., supplied to a gate of M31) to connect a supply voltage (VDD; e.g., connected to a source of M31) to the other transistors. For example, M31 can be OFF when the write enable signal is at an inactive high level, such as when no data signal to be written is supplied to the input buffer 100, thereby reducing a leakage current. A source of another P-channel transistor (M30; controlled by the DQSB supplied to a gate thereof) can be connected to a drain of M31. A drain of M30 can be connected to sources of one or more further P-channel transistors (M1 and/or M2) operated by the DQ signal connected to gates thereof. In one or more embodiments, M1 and/or M2 can be a differential amplifier or a portion thereof such that the gate of M1 is connected to a positive connection of the DQ signal and M2 is connected to a negative connection of the DQ signal (e.g., a reference node (Vref)). Drains of M1 and/or M2 can be connected to ground through corresponding precharging transistors (e.g., N-channel transistors M7 and M8, respectively) that are operated by the DQST signal connected to the gates of the M7 and/or M8. The precharging transistors (M7, M8, M30, M27, M28, M29, or a combination thereof) can be operated according to a data strobe signal (DQS) or derivatives thereof (e.g., the DQST and/or the DQSB signals) to precharge the respective nodes.

In some embodiments, the drains of M1 and/or M2 can further be connected to gates of corresponding N-channel transistors (M26 and M27, respectively) for further amplifying an output of the differential amplifier (e.g., M1 and M2). Sources and drains of the amplifying transistors (M26 and/or M27) can be connected to a series of transistors connected to a source of M31 and a drain of M30. For example, the sources of the amplifying transistors M26 and/or M27 can be connected to ground through one or more current control transistors (e.g., N-channel transistors M40 and/or M41). Also, the drains of the amplifying transistors M26 and/or M27 can be connected to one or more latching transistors (e.g., M14, M15, M16, and/or M17 for holding logic level amplified by M1, M2, M26, and/or M27) and/or one or more precharging transistors (e.g., M28 and/or M29). In some embodiments, sources of the latching transistors and/or the precharging transistors (e.g., M14, M15, M28, and/or M29) can be connected to the drain of M31 and the source of M30. Drains of the upstream output transistors can generate the output signal. For example, the drains of M28 and M14 can generate a differential high portion of the output signal (OUT+) and the drains of M29 and M15 can generate a differential negative portion of the output signal (OUT−). One or more of the upstream output transistors (e.g., M14 and/or M15) can be operated according to the opposing differential output connected to the gates thereof. For example, the gate of M14 can be connected to OUT− and/or the gate of M15 can be connected to OUT+. Some of the other upstream output transistors (e.g., M28 and/or M29) can be operated according to the DQST signal connected to the gates thereof. In some embodiments, the nodes that corresponding to OUT+ and/or OUT− can be further connected to one or more downstream transistors (e.g., N-channel transistors M16 and/or M17). For example, drain of M16 can be connected to a capacitor C1 and the OUT+ node, and drain of M17 can be connected to a capacitor C2 and the OUT− node. Also, source of M16 can be connected to drain of M26, and source of M17 can be connected to drain of M27. In this example, the source of M16 and the source of M17 can be connected to a source and a drain of a transistor M10, respectively. As shown in FIG. 1, the source of M10 can be connected with capacitor C3 and the drain of M10 can be connected with capacitor C4. Each one of the capacitors C1, C2, C3, and C4 can be connected with a ground voltage (VSS). In the input buffer 100, the gates of the downstream transistors can be operated by the opposing differential output, such as by having gate of M16 connected to the OUT− node and by having gate of M17 connected to the OUT+ node.

The input buffer 100 can include the sectional transistor device 200 for one or more of the transistors described above. For example, the sectional transistor device 200 can be used at one or more locations in the DQ input buffer, such as for amplifying the logic level (e.g., increasing a gain to operate at a high speed). In one or more embodiments, the sectional transistor device 200 can be used to connected with output nodes, such as OUT+ and/or OUT− nodes, wherein they can be further connected to one or more downstream transistors. In one or more embodiments, the sectional transistor device 200 can be used to initially receive the DQ signal, such as for the P-channel transistors M1 and/or M2 where the DQ signal is connected to the gate connector. In one or more embodiments, one or more sets of the sectional transistor device 200 can be implemented in the DQ input buffer as differential amplifiers (e.g., M1 and/or M2), second stage amplifier (e.g., M26 and M27), etc.

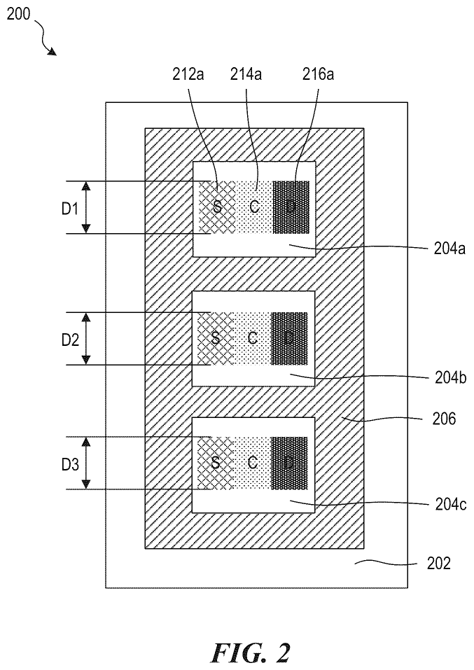

FIG. 2 illustrates a first plan-view exemplary layout of the sectional transistor device 200 in accordance with an embodiment of the present technology. The sectional transistor device 200 can include a first section 204a, a second section 204b, and a third section 204c. The first section 204a, the second section 204b, and the third section 204c can each include one or more channels (e.g., individual transistor units). In some embodiments, the first section 204a, the second section 204b, and the third section 204c can include a same number of channels.

In this example, the first section 204a, the second section 204b, and the third section 204c can be fabricated in a same substrate 202. Each of the sections can be active regions that are doped with dopant semiconductor materials such as boron or phosphorus. The first section 204a, the second section 204b, and the third section 204c can be formed by ion implanting a same type of dopant material to create a p-type or a n-type active regions in the substrate 202. Specifically, the first section 204a, the second section 204b, and the third section 204c are separate (e.g., non-contiguous bodies of semiconductive material) from each other. In some embodiments, the sectional transistor device 200 can include a shallow trench isolation (STI) region 206 disposed among the first section 204a, the second section 204b, and the third section 204c and separates these three sections. The first section 204a, the second section 204b, and the third section 204c can each include regions that are doped to form sources, drains, and channels. For example, the first section 204a includes a doped source region 212a, a doped drain region 216a, and a channel region 214a disposed therebetween. The sectional transistor device 200 can include conductive structures (e.g., wires, traces, pads, etc.) that respectively connect to the doped source or drain regions. Above the top surface of the substrate 202, there may be one or more gate structures disposed above each of the first, second, and third sections. The one or more gate structures can be made of a thin layer of metal or polysilicon and separated from the semiconductor channel regions (e.g., 214a) by a thin layer of dielectric. Further, a gate connector (e.g., a conductive structure having multiple legs/extensions) can be connected to the gate structures between each pairing of source and drain. Also, at various contacts, a source connector can directly contact the source region (e.g., 212a of the substrate 202 and a drain connector can directly contact the drain region (e.g., 216a) of the substrate 202. In some other embodiments, each of the first section 204a, the second section 204b, and the third section 204c can be fabricated in separate substrates or dies and interconnected during the chip packaging.

Also, the first section 204a, the second section 204b, and the third section 204c can each include one or more channels (e.g., channel 214a) that are arranged parallel to each other, such as in rows or columns. The first section 204a can include channels that have a first channel width D1, the second section 204b can include channels that have a second channel width D2, and the third section 204c can include channels that have a third channel width D3. The channel width D1, D2, and D3 of the sectional transistor device 200 can be same or different. The channel width of each section regions may be defined by corresponding dimensions of the source region and drain region, and may be equal to a width of corresponding action region.

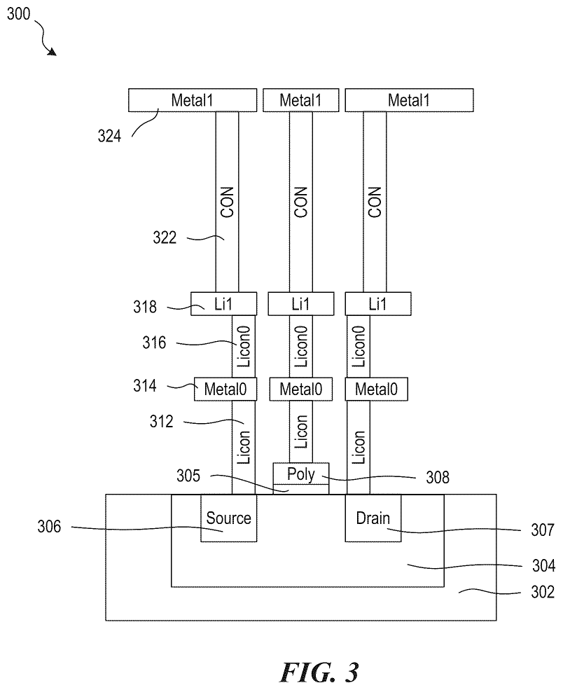

In some embodiments, the channels of the first section 204a, the second section 204b, and the third section 204c can be arranged such that they are respectively colinear. For example, for the embodiment illustrated in FIG. 2, the first section 204a can be located ahead (e.g., on top as illustrated in FIG. 3) of the second section 204b which is further located ahead of the third section 204c. The sources, channels (gates), drains of the first section 204a can be aligned with those of the second section 204b and third section 204c, respectively. Accordingly, the gate connector, the source connector, and the drain connector (not included in this layout) can include parallel legs that extend across a same direction (e.g., a vertical direction on the layout plane). As such, each of the connectors for the source, gate, and drain regions can be connected in series on a higher wiring level. As a result, the source region, gates, and drain regions on the first section 204a, the second section 204b, and the third section 204c can be connected electrically in series within the sectional transistor device 200.

Based on connecting a set of channels in series, the sectional transistor device 200 can provide the increased number of channels without the increasing the interconnects. For comparison to a conventional transistor device having a channel width D, the first section channel width D1, the second section channel width D2, and the third section channel width D3 can be the same, which is one third of the channel width D of conventional transistor device (i.e., D₁=D₂=D₃=1/3 D). Also, the sectional transistor device 200 can have the same number of total channels (e.g., three channels) as the conventional transistor device. Based on connecting a set of channels in series, the sectional transistor device 200 can have a total number (e.g., three) of colinear sets of channels as the total number of channels in the conventional transistor device. Accordingly, the sectional transistor device 200 can have the same total width for the colinear set of channels as the channel width of the conventional transistor device and matching number of connector legs. As such, the sectional transistor device 200 can provide increased drain-source current (e.g., in comparison to the conventional transistor device) with reduced parasitic interconnection capacitance. The higher operating speed and the reduced parasitic interconnection capacitance (e.g., based on reduced number of connector legs), allows the sectional transistor device 200 to operate at higher speeds than the conventional transistor device having all source regions, channels and drain regions disposed in a same action region of the substrate. Alternatively, the sectional transistor device 200 can provide the same source-drain current with reduced size (e.g., reduced total width of the transistor device) in comparison to layouts of the conventional transistor device.

In some other embodiments, the sectional transistor device 200 may include two sections that are parallelly aligned. For example, the sectional transistor device 200 may only include the first section 204a and the second section 204b in the substrate 202. The first section 204a and the second section 204b may be active regions formed in the substrate 202 and can be electrically separated by the STI region 206. The source, channel, drain regions of each of the first section 204a and the second 204b can be respectively aligned along the vertical direction. The source regions, drain regions, and gates included in the sectional transistor device 200 can be respectively interconnected through a higher wiring level. In some other embodiments, the sectional transistor device 200 may include more than three sections that are aligned along a specific direction and separated by the STI region 206 in the substrate 202.

FIG. 3 illustrates a cross-sectional view of a transistor device 300 and its multiple levels of wiring interconnections in accordance with an embodiment of the present technology. Here, the transistor device 300 can be disposed in each section of the sectional transistor device. For example, each one of the first section 204a, second section 204b, and third section 204c of the sectional transistor device 200 described in FIG. 2 may include a transistor device and corresponding multiple levels of wiring interconnections as shown in the FIG. 3. As shown, the transistor device 300 may includes a gate 308, a source region 306, and a drain region 307, all of which being embedded in a section of the substrate 302, e.g., a P-well active region 102. In some embodiments, the gate 308 may be formed of polysilicon or conductive metals. There may be a gate dielectric layer 305 disposed below the gate 308 and made of gate oxide material (e.g., silicon dioxide, and/or silicon nitride). The source and drain regions 306 and 307 can be formed within the section region 304 of the substrate 302, and may be heavily doped by a N-type dopant material. In addition, the active region 304 can be doped by a P-type dopant material (e.g., doped with Boron and/or Gallium). Generally, the source region 306 and the drain region 307 have higher concentration of dopants than the section region 304. Further, the region embedded in the section region 304 and is directly below the gate 308 and between the source region 306 and the drain region 307 is referred as a channel region of the transistor device 300. In this example, the source region 306, the drain region 307, and the section region 304 disposed in the substrate 302 can be isolated by a STI region surrounding the section region 304. The STI region can be made of dielectric materials to provide better isolation/prevent cross-talk between electrical devices disposed on the frontside surface of the substrate 302. Specifically, the STI 118 can be made of materials including tetraethyl orthosilicate (TEOS), silicon oxide (SiO), silicon nitride (SiN), silicon borocarbonitride (SiBCN), silicon oxycarbonitride (SiOCN), silicon oxycarbide (SiOC), silicon carbonitride (SiCN), silicon boronitride (SiBN), a low-k dielectric material, or a combination thereof.

In this example, each one of the source region 306 and drain region 307 can be connected to a corresponding metal-0 layer 314, through a via 312, for interconnections with other semiconductor devices of a circuit (e.g., a memory data queue input buffer circuit). Here, the metal-0 layers respectively connected to the source region 306 and drain region 307 can be electrically isolated by dielectric materials. Moreover, each via 312 can be processed by patterning a hole in a dielectric layer disposed above the substrate 302 and filling with electrically conductive materials including metals such as cooper, tungsten, gold, nickel, aluminum, silver, or metal alloys. In this example, the gate 308 can also be connected to a dedicated metal-0 layer, through a via 312, for interconnections. Each of the metal-0 layers 314 that are dedicated to corresponding source region 306, gate 308, or drain region 307 can be processed by patterning a metal layer deposited above the via connections 312 through a photolithography technique. In this example, the metal-0 layers 314 can be made of electrically conductive materials including metals such as copper, tungsten, molybdenum, nickel, titanium, tantalum, platinum, silver, gold, ruthenium, iridium, rhenium, rhodium, or alloys thereof.

Once the metal-0 layer is formed, in this example, an intermediate wiring layer (e.g., Li1 layer) can be formed there above. Specifically, each one of the source region 306, gate 308, and drain region 307 can be connected to a corresponding Li1 layer 318 through corresponding metal-0 layer 314 and corresponding via 316 disposed between the metal-0 layer 314 and the Li1 layer 318. As shown the Li1 layers 318 can be electrically separate from each other and isolated by dielectric materials. In the transistor device 300, control signals can be delivered to the source region 306, gate 308, and drain region 307 through Li1 layers 318 and metal-0 layers 314, respectively.

As described in FIG. 2, the sectional transistor device 200 may include multiple sections in the substrate, each section including a transistor device having a source region, a drain region, and a gate. The sections can be parallelly aligned so that the source regions, the drain regions, and the gate regions can be aligned along a certain direction. In this example, the intermediate interconnect layer Li1 318 can be respectively connected to each one of the source regions, drain regions, or gates that are disposed in different sections. For example, when the sections of the sectional transistor device 200 are vertically aligned, each one of the intermediate Li1 layers 318 can be extended along the vertically direction, connecting the source region, drain region, or gate of each one of the sections of the sectional transistor device 200. In some other embodiments, the sections of the sectional transistor device 200 may be aligned along a horizontal direction, having its source region, drain region and gate vertically aligned. Accordingly, each one of the intermediate Li1 layers 318 can be extended along the horizontal direction, to connect corresponding source regions, drain regions, or gates of each one of the sections of the sectional transistor device 200. In the present technology, the intermediate Li1 layer is utilized to electrically connect corresponding regions (e.g., a source, a drain, or a gate) of each one of the sections (i.e., active regions).

The transistor device 300 also includes metal-1 layers 324 disposed above the intermediate Li1 layer 318 and configured for more complex interconnects to other parts of the transistor device or circuits. The metal-1 layers 324 can be respectively connected to the metal-0 layers 318 through via interconnects 322. The via interconnects 322 can be processed similarly to the vias 312 and 316, and made of similar electrically conductive materials including tungsten, copper, and/or their alloys. In addition, the metal-1 layers 324 can be made of conductive materials such as copper or silver. During the operation of sectional transistor device 200, control signals or voltages can be applied on the metal-1 layers 324 and further delivered to the source region 306, the gate 308, or the drain region 307 of one or more transistor devices 300 included in the sectional transistor device 200. In this example, each one of the intermediate Li1 layers and the metal-1 layers can be made of conductive materials including copper, tungsten, molybdenum, nickel, titanium, tantalum, platinum, silver, gold, ruthenium, iridium, rhenium, rhodium, or alloys thereof.

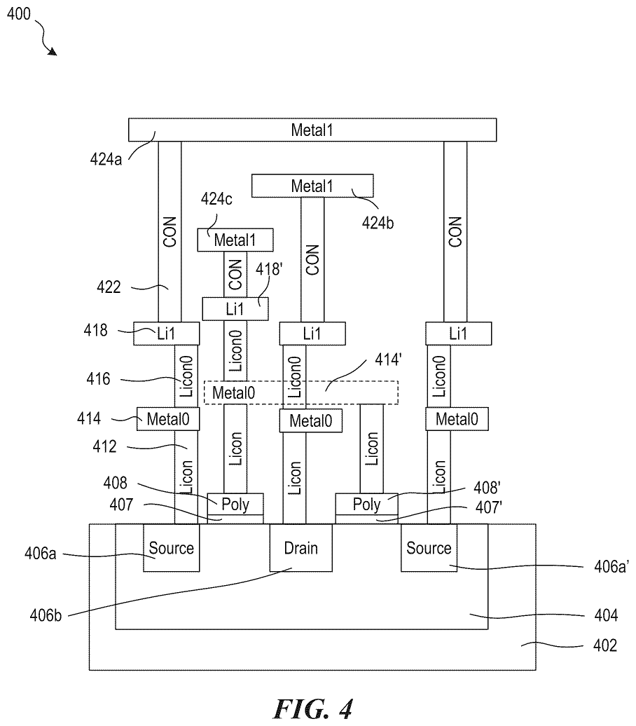

Each section of the sectional transistor device 200 can include multiple doped regions, e.g., one or more source regions, one or more channels, and one or more drain regions, in the transistor device included therein. For example, the sections of the sectional transistor device 200 can each include two source regions, two channels, and one drain region in the substrate 202. FIG. 4 illustrates a cross-sectional view of another transistor device 400 and its multiple levels of wiring interconnections in accordance with an embodiment of the present technology. The transistor device 400 can be disposed in each section of the sectional transistor device 200 and include two source regions 406a and 406a′, and one drain region 406b. The transistor device 400 can also include two gates 408 and 408′ that are disposed horizontally between the source region 406a or 406a′ and the drain region 406b. As shown, the drain region 406b is shared by the transistor structures disposed on the left hand side and the right hand side of the transistor device 400, i.e., two channels under the gate 407 and 407′ can be connected to the drain region 406b. During an operation of the transistor device 400, currents can flow from the source regions 406a and 406a′ to the drain region 406b, respectively.

Similar to the transistor device 300, the transistor device 400 may include a gate dielectric layer 407 under each one of the gates 408 and 408′, the gate dielectric layer 407 being made of gate oxide materials (e.g., silicon dioxide, and/or silicon nitride). The transistor device 400 also include metal-0 layers 414 that are respectively connected to the source regions 406a and 406a′, drain region 406b, and gates 408 and 408′, respectively through vias 412. The material composition and fabrication processes of the metal-0 layers 414 and vias 412 can be similar to the metal-0 layers 314 and vias 312 described in FIG. 3. In this example, the gates 408 and 408′ are interconnected through the metal-0 layer 414′. During the operation of the transistor device 400, a gate control voltage can be applied to both of the gates 408 and 408′ through the metal-0 layer 414′. In addition, the metal-0 layers (e.g., 414 and 414′) connected to corresponding source regions, drain region, and gates are electrically isolated by dielectric materials disposed therebetween to avoid electric interconnection.

As shown in FIG. 4, the transistor device 400 may include a group of intermediate Li1 layers 418 and 418′ connected to each one of the source regions, drain regions, and gates included in the substrate 402, respectively. In addition, the transistor device 400 may include one additional intermediate Li layer 418 connected, through a metal-0 layer 414′, to the gates 408 and 408′. In this example and as described in FIG. 2, the sectional transistor device 200 may include multiple sections in its substrate, each section including a transistor device having one or more source regions, one or more drain regions, and one or more gates. The sections can be parallelly aligned so that the source regions, the drain regions, and the gate regions can be aligned along a certain direction. For example, the intermediate interconnect Li1 layers 418 and 418′ can be respectively connected to each one of the source regions and drain regions, and gates that are disposed in different sections of the sectional transistor device 200. Specifically, when the sections of the sectional transistor device 200 are vertically aligned, each one of the intermediate Li1 layers 418 can be extended along the vertically direction, connecting the source regions, drain regions, or gates of each one of the sections of the sectional transistor device 200. In some other embodiments, the sections of the sectional transistor device 200 may be aligned along a horizontal direction, having its source regions, drain regions, and gates vertically aligned in each sections. Accordingly, each one of the intermediate Li1 layers 418 can be extended along the horizontal direction, to connect corresponding source regions, drain regions, or gates of each one of the sections of the sectional transistor device 200.

The transistor device 400 may also include metal-1 layers 424 disposed above the intermediate Li1 layer 418 and configured for more complex interconnects to other parts of the transistor device or circuits. The metal-1 layers 424 includes a source finger 424a, a drain finger 424b, and a gate finger 424c, which can be respectively connected to source regions 406a and 406a′, drain region 406b, and gates 408 and 408′, through corresponding via interconnects 422. In this example, the intermediate Li1 layers 418 that are connected to the multiple source regions (e.g., the source regions 406a and 406a′) can be interconnected with the metal-1 layer source finger 424a. With this configuration, a same source control voltage can be applied, through the metal-1 layer source finger 424a, to both source regions 406a and 406a′ in the operation of the transistor device 400. In this example, the shared gate control voltage through the Metal-0 layer 414′ and shared source region control voltage through the Metal-1 layer source finger 424a make the transistor device 400 to be a two-fold symmetric, having mirrored source-drain current flow from one of the source regions 406a or 406a′ to the drain region 406b. The transistor device 400 may have a doubled source drain current in comparison to the transistor device 300 which only includes a single channel structure.

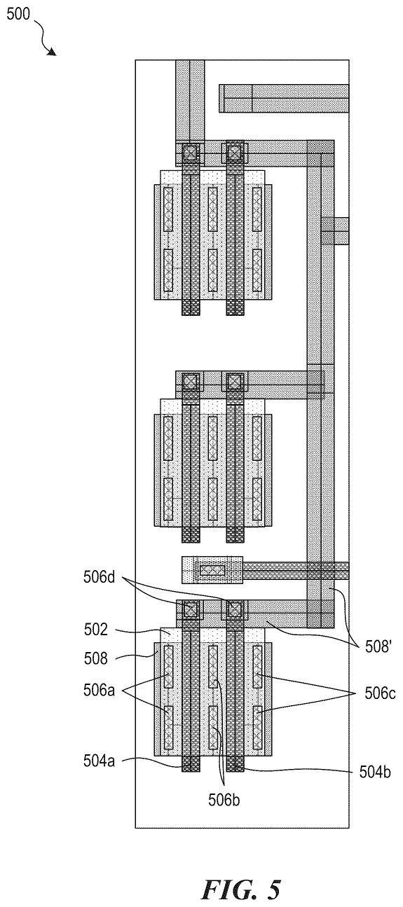

The present technology includes specific interconnect wiring layers such as metal-0 layers, intermediate Li1 layers, metal-1 layers, and vias connecting the wiring layers to interconnect the multiple sections (active regions) and operate a sectional transistor device (e.g., the sectional transistor device 200) as an individual transistor device. FIG. 5 illustrates a plan view of a second layout 500 of the sectional transistor device 200 in accordance with an embodiment of the present technology. Specifically, the sectional transistor device 200 includes three section/active regions, each section/active regions including a transistor device 400 as shown in FIG. 4. The layout of FIG. 5 shows three active regions vertically aligned from top to bottom. Each section includes an active region (e.g., active region 502), gates (e.g., gates 504a and 504b), metal-0 layers (e.g., metal-0 layers 508), and vias connecting the doped regions of the action region and corresponding metal-0 layers (e.g., Licon vias 506a, 506b, and 506c). As described in FIG. 4, the transistor device 400 each includes two source regions, one drain region, and two gates. The one drain region is disposed between the two source regions and the two gates are respectively disposed between corresponding source region and the drain region. In this example, the first source region (the active region under contacts 506a), first gate 504a, drain region (the active region under vias 506d), second gate 504b, and the second source region (the active region under contacts 506c) are aligned along a first direction on the layout 500 (e.g., horizontally aligned from left to right in the bottom transistor section as shown in FIG. 5). Each one of the source regions and drain region of the active section 502 is connected to corresponding metal-0 layer 508 through corresponding vias (e.g., vias 506a, 506b, or 506c). The gates 504a and 504b are parallelly aligned along the vertical direction and are interconnected, through a pair of vias 506d, to the metal-0 layer 508′ partially aligned and adjacent to the active region 502. In this example, the gates 504a and 504b may have a same gate width and a same gate length.

In this example, the wiring connections may have similar profiles among the multiple sections of the sectional transistor device 200. Particularly, the Licon vias (e.g., vias connecting the source regions or drain regions of the active regions) connected to each active regions and each gate are correspondingly aligned along a second direction orthogonal to the first direction. For example, each one of the via contacts 506a, 506b, 506c, and 506d of the section regions included in the sectional transistor device 200 are aligned along the vertical direction, respectively. This configuration may enable a simple patterning process in fabricating the interconnect wiring layers that connect the multiple section regions. In this example, each one of the active regions of the sectional transistor device 200 has dedicated one or more gates. For example and as shown in FIG. 5, the first and second gates 504a and 504b are disposed above the bottom active region 502 and are isolated from other transistor components disposed within or above other active regions. In the present technology, the interconnection of gates (e.g., applying a same gate control voltage to the gates included in the sectional transistor device 200) among the sections of the sectional transistor device 200 can be conducted through the interconnect wiring layers including the metal-0 layer 508′.

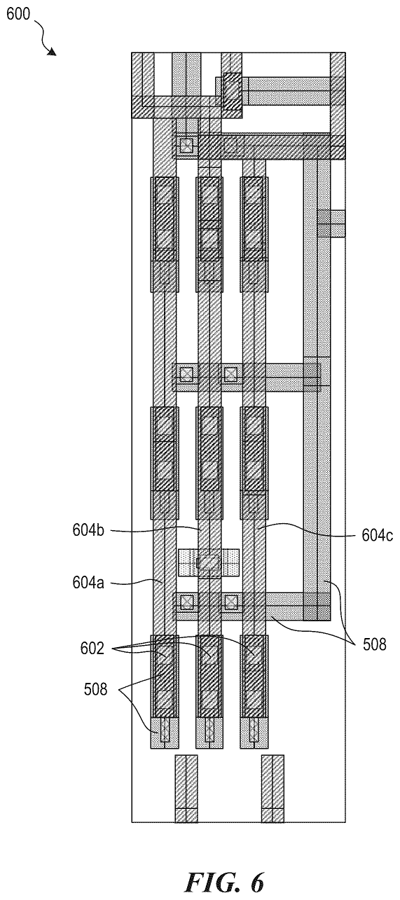

FIG. 6 illustrates a plan view of a third layout 600 of the sectional transistor device 200 in accordance with an embodiment of the present technology. Specifically, in comparison to that of the FIG. 5, FIG. 6 describes a higher level of interconnect wiring layers including intermediate finger layer 604 (e.g., finger 604a, finger 604b, and finger 604c) and vias 602 that connect the intermediate finger layers to corresponding metal-0 layers. In this example, the intermediate finger layers are respectively connected, through corresponding metal-0 layers, to corresponding source region or drain region. For example, the intermediate finger layer 604a can be connected to the first source region of each section region of the sectional transistor device 200. In addition, the intermediate finger layer 604b can be connected to the drain region of each section region of the sectional transistor device 200. Further, the intermediate finger layer 604c can be connected to the second source region of each section region of the sectional transistor device 200. In this example, each one of the intermediate finger layers can be in a stripe shape, extending along the direction that corresponding contacts of each doped regions of active regions are aligned to. Through the intermediate wiring layers described in FIG. 6, a source control voltage can be applied, through the intermediate finger layers 604a and 604c, on the first and second source regions of each one of the active regions of the sectional transistor device 200. Similarly, a drain control voltage can be applied, through the intermediate finger layer 604b, on the drain region of each one of the active regions of the sectional transistor device 200.

In the present technology, the intermediate wiring layers can be further connected to a higher level wiring layers such as metal-1 layers for complex interconnection. For example, the intermediate finger layers 604a and 604c can be connected to a metal-1 layer, through via contacts, so that a source control voltage can be applied on both source regions of each one of the active regions of the sectional transistor device 200. In addition, the intermediate finger layers connected to the gates and drain regions of each one of the active regions of the sectional transistor device 200 can be connected to corresponding metal-1 layers for gate control signal and drain control signal transmission.

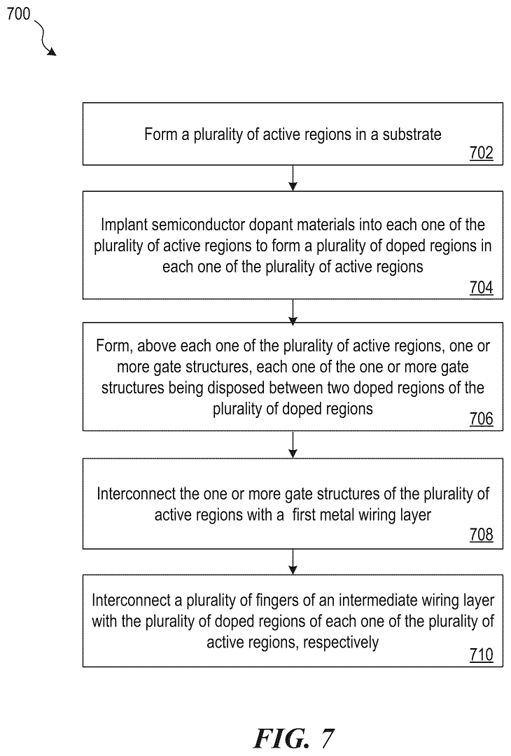

FIG. 7 is a flow diagram illustrating an example method of manufacturing the sectional transistor device 200 in accordance with an embodiment of the present technology. For example, the method 700 includes forming a plurality of active regions in a substrate, at 702. For example, the first section 204a, the second section 204b, and the third section 204c can be fabricated in a same substrate 202 as described in FIG. 2. Each of the sections can be formed by ion implanting a same type of dopant material to create a p-type or a n-type active regions in the substrate 202.

The method 700 also includes implanting semiconductor dopant materials into each one of the plurality of active regions to form a plurality of doped regions in each one of the plurality of active regions, at 704. For example, the doped source region 212a, the doped drain region 216a, and the channel region 214a disposed therebetween can ab formed in the first section 204a of the sectional transistor device 200. The doped source region 212a and the doped drain region 216a may have a higher doping level compared to the first section/active region 204a.

The method 700 further includes forming, above each one of the plurality of active regions, one or more gate structures, each one of the one or more gate structures being disposed between two doped regions of the plurality of doped regions, at 706. For example, the gate structure 308 can be formed above the substrate 302 of the transistor device 300. The gate 308 can be high-K metal gate and isolated from the substrate 302 by a gate dielectric layer 305. In another example, the first gate 408 and the second gate 408′ can be formed above the substrate 402. Specifically, the first gate 408 can be disposed between the first source 406a and the drain 406b, and the second gate 408′ can be disposed between the second source 406a′ and the drain 406b.

In addition, the method 700 includes interconnecting the one or more gate structures of the plurality of active regions with a first metal wiring layer, at 708. For example, the gate 308 can be connected, through a via 312, to the metal-0 layer 314 in the transistor device 300. In another example, the first gate 408 and second gate 408′ can both be connected with the metal-0 layer 414′, as shown in FIG. 4.

Lastly, the method 700 includes interconnecting a plurality of fingers of an intermediate wiring layer with the plurality of doped regions of each one of the plurality of active regions, respectively, at 710. For example, the intermediate Li1 layers 318 are respectively connected to, through corresponding metal-0 layers 314, the source region 306 and drain region 307 as shown in FIG. 3. In another example, the fingers of the intermediate layer 604 (e.g., the fingers 604a, 604b, and 604c) can be connected to the first source region, the drain region, and the second source region of the active region 502, as shown in FIG. 6.

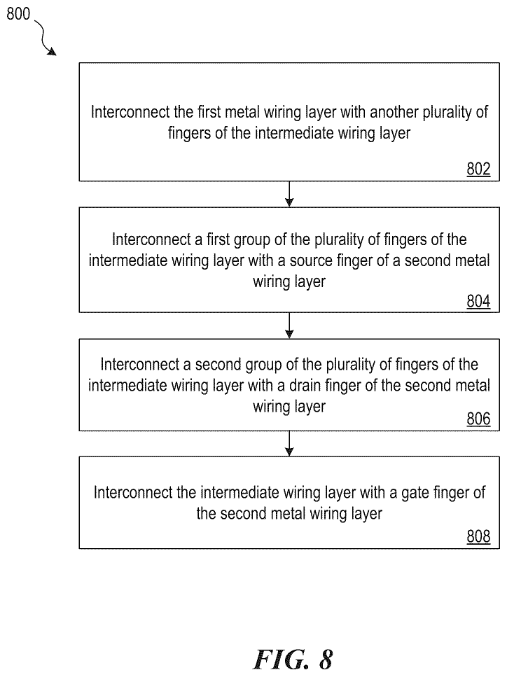

Turning to FIG. 8 which is a flow chart illustrating another method 800 of processing the sectional transistor device 200 in accordance with embodiments of the present technology. The method 800 includes interconnecting the first metal wiring layer with another plurality of fingers of the intermediate wiring layer, at 802. For example, each one of the metal-0 layers 314 is connected, through corresponding vias 316, to the intermediate finger layers 318, respectively.

The method 800 also includes interconnecting a first group of the plurality of fingers of the intermediate wiring layer with a source finger of a second metal wiring layer, at 804. For example, the intermediate finger layers 604a and 604c can be connected, through corresponding vias, to a metal-1 layer that a same source control voltage can be applied through the metal-1 layer, and the intermediate finger layers 604a and 604c, to the first and second source regions of each one of the sections (e.g., section 502) of the sectional transistor device 200 described in FIGS. 5 and 6.

Further, the method 800 includes interconnecting a second group of the plurality of fingers of the intermediate wiring layer with a drain finger of the second metal wiring layer, at 806. For example, the intermediate finger layer 604b can be connected, through a corresponding via, to another metal-1 layer to transmit a drain control voltage to the drain region included in each section of the sectional transistor device 200, as described in FIG. 6.

Lastly, the method 800 includes interconnecting the intermediate wiring layer with a gate finger of the second metal wiring layer, at 808. For example, the intermediate finger layer 418′ which is connected, through the metal-0 layer 414′, to the first gate 408 and the second gate 408′ can be further connected to the higher level metal-1 layer 424c, to transmit a gate control voltage to the first and second gates included in each section of the sectional transistor device 200, as describe in FIGS. 4 to 6.

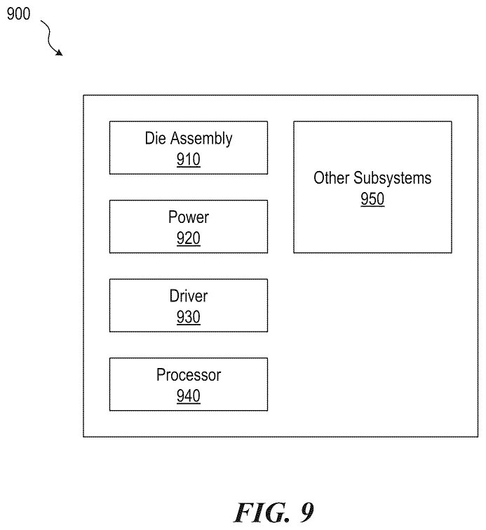

Any one of the semiconductor structures described above with reference to FIGS. 1-8 can be incorporated into any of a myriad of larger and/or more complex systems, a representative example of which is system 900 shown schematically in FIG. 9. The system 900 can include a semiconductor device 910, a power source 920, a driver 930, a processor 940, and/or other subsystems or components 950. The semiconductor device 910 can include features generally similar to those of the semiconductor devices described above and can therefore include section regions described in the present technology. The resulting system 900 can perform any of a wide variety of functions, such as memory storage, data processing, and/or other suitable functions. Accordingly, representative systems 900 can include, without limitation, hand-held devices (e.g., mobile phones, tablets, digital readers, and digital audio players), computers, and appliances. Components of the system 900 may be housed in a single unit or distributed over multiple, interconnected units (e.g., through a communications network). The components of the system 900 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (FeRAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device, comprising:
a first transistor region, comprising:
a first active region disposed in a substrate of the semiconductor device, the first active region including one or more first transistor source regions and one or more first transistor drain regions, and
one or more first transistor gate structures disposed above the first active region;
a second transistor region, comprising:
a second active region disposed in the substrate and physically separated from the first active region, the second active region including one or more second transistor source regions and one or more second transistor drain regions, and
one or more second transistor gate structures disposed above the second active region, the one or more second transistor gate structures being physically separated from the one or more first transistor gate structures;
a first metal wiring layer having one or more fingers that are connected to the one or more first transistor gate structures and the one or more second transistor gate structures, respectively;
an intermediate wiring layer having one or more first fingers and one or more second fingers, wherein the one or more first transistor source regions and the one or more second transistor source regions are connected to the one or more first fingers, respectively, and the one or more first transistor drain regions and the one or more second transistor drain regions are connected to the one or more second fingers, respectively; and
a second metal wiring layer having a source finger, a drain finger, and a gate finger, wherein the source finger is connected to the one or more first fingers of the intermediate wiring layer, the drain finger is connected to the one or more second fingers of the intermediate wiring layer, and the gate finger is connected to the one or more fingers of the first metal wiring layer.

2. The semiconductor device of claim 1, wherein the first active region and the second active region are aligned along a first direction, the one or more first transistor source regions are respectively aligned with the one or more second transistor source regions along the first direction, the one or more first transistor drain regions are respectively aligned with the one or more second transistor drain regions along the first direction, and the one or more first transistor gate structures are respectively aligned with the one or more second transistor gate structures along the first direction.

3. The semiconductor device of claim 2,
wherein the one or more first transistor source regions and the one or more second transistor source regions share, through the one or more first fingers of the intermediate wiring layer and the source finger of the second metal wiring layer, a same source operating voltage,
wherein the one or more first transistor drain regions and the one or more second transistor drain regions share, through the one or more second fingers of the intermediate wiring layer and the drain finger of the second metal wiring layer, a same drain operating voltage, and
wherein the one or more first transistor gate structures and the one or more second transistor gate structures share, through the one or more fingers of the first metal wiring layer and the gate finger of the second metal wiring layer, a same gate operating voltage.

4. The semiconductor device of claim 2, wherein the one or more first transistor source regions, the one or more first transistor drain regions, and the one or more first transistor gate structures are aligned along a second direction orthogonal to the first direction, and wherein the one or more second transistor source regions, the one or more second transistor drain regions, and the one or more second transistor gate structures are aligned along the second direction.

5. The semiconductor device of claim 3, wherein one of the one or more first transistor drain regions is disposed between adjacent two first transistor source regions of the one or more first transistor source regions along the second direction, and wherein one of the one or more second transistor drain regions is disposed between adjacent two second transistor source regions of the one or more second transistor source regions along the second direction.

6. The semiconductor device of claim 1, wherein each of the first metal wiring layer, the intermediate wiring layer, and the second metal wiring layer is made of conductive materials including copper, tungsten, molybdenum, nickel, titanium, tantalum, platinum, silver, gold, ruthenium, iridium, rhenium, rhodium, or alloys thereof.

7. The semiconductor device of claim 1, wherein the one or more first transistor gate structures and the one or more second transistor gate structures have a same gate width and a same gate length.

8. The semiconductor device of claim 1, wherein the first active region and the second active region are isolated by a shallow trench isolation (STI) region disposed in the substrate.

9. The semiconductor device of claim 1, wherein the semiconductor device is a volatile memory device including a dynamic random access memory (DRAM) and/or a static random access memory (SRAM).

10. The semiconductor device of claim 1, further comprising:
a third transistor region, comprising:
a third active region disposed in the substrate and physically separated from the first and the second active regions, the third active region including one or more third transistor source regions and one or more third transistor drain regions, and
one or more third transistor gate structures disposed above the third active region, the one or more third transistor gate structures being physically separated from the one or more first transistor gate structures and the one or more second transistor gate structures,
wherein the one or more fingers of the first metal wiring layer are connected to the one or more first transistor gate structures, the one or more second transistor gate structures, and the one or more third transistor gate structures, respectively, and
wherein the one or more third transistor source regions are respectively connected to the one or more first fingers, and the one or more third transistor drain regions are respectively connected to the one or more second fingers.

11. The semiconductor device of claim 1, wherein the first active region includes two first transistor source regions, one first transistor drain region, and two first transistor gate structures, the one first transistor drain region being disposed between the two first transistor source regions and each of the two first transistor gate structures being disposed between the one first transistor drain region and corresponding one of the two first transistor source regions.

12. The semiconductor device of claim 11, wherein the second active region includes two second transistor source regions, one second transistor drain region, and two second transistor gate structures, the one second transistor drain region being disposed between the two second transistor source regions and each of the two second transistor gate structures being disposed between the one second transistor drain region and corresponding one of the two second transistor source regions.

13. The semiconductor device of claim 11,
wherein both two first transistor source regions are connected, respectively through two fingers of the one or more first fingers of the intermediate wiring layer, to the source finger of the second metal wiring layer, and
wherein both two first transistor gate structures are connected to a first gate finger of the first metal wiring layer.

14. The semiconductor device of claim 13,
wherein both two second transistor source regions are connected, respectively through the two fingers of the one or more first fingers of the intermediate wiring layer, to the source finger of the second metal wiring layer, and
wherein both two second transistor gate structures are connected to a second gate finger of the first metal wiring layer.

15. A method of forming a semiconductor device, comprising:
forming a plurality of active regions in a substrate;
implanting semiconductor dopant materials into each one of the plurality of active regions to form a plurality of doped regions in each one of the plurality of active regions;
forming, above each one of the plurality of active regions, one or more gate structures, each one of the one or more gate structures being disposed between two doped regions of the plurality of doped regions;
interconnecting the one or more gate structures of the plurality of active regions with a first metal wiring layer; and
interconnecting a plurality of fingers of an intermediate wiring layer with the plurality of doped regions of each one of the plurality of active regions, respectively.

16. The method of claim 15, further comprising:
interconnecting the first metal wiring layer with another plurality of fingers of the intermediate wiring layer;
interconnecting a first group of the plurality of fingers of the intermediate wiring layer with a source finger of a second metal wiring layer;
interconnecting a second group of the plurality of fingers of the intermediate wiring layer with a drain finger of the second metal wiring layer; and
interconnecting the intermediate wiring layer with a gate finger of the second metal wiring layer.

17. The method of claim 16, wherein forming the plurality of doped regions including forming a plurality of source regions and a plurality of drain regions in each one of the plurality of active regions, wherein the plurality of source regions and the plurality of drain regions are alternatively aligned in series in the substrate, wherein each one of the one or more gate structures is disposed between a corresponding source region and a corresponding drain region, and wherein forming the plurality of active regions includes implanting dopant materials into each one of the plurality of active regions in the substrate, the plurality of active regions being physically separated by corresponding STI regions disposed in the substrate.

18. The method of claim 17, wherein the plurality of source regions disposed in each one of the plurality of active regions are connected to the first group of the plurality of fingers of the intermediate wiring layer, respectively, and wherein the plurality of drain regions disposed in each one of the plurality of active regions are connected to the second group of the plurality of fingers of the intermediate wiring layer, respectively.

19. The method of claim 16, wherein the plurality of active regions are fabricated to be aligned along a first direction, the plurality of doped regions in each one of the plurality of active regions are aligned along a second direction orthogonal to the first direction, and the one or more gate structures are aligned along the first direction in each one of the plurality of active regions.

20. The method of claim 16, further comprising:
forming a first plurality of via connections above the first metal wiring layers, wherein the intermediate wiring layer is connected to the first metal wiring layers through the first plurality of via connections; and
forming a second plurality of via connections above the intermediate wiring layer, wherein the second metal wiring layer is connected to the intermediate wiring layer through the second plurality of via connections.
